(19) United States
(12) Patent Application Publication
(10) Pub. No.: US 2012/0154072 A1
(43) Pub. Date: Jun. 21, 2012

(54) FBAR DUPLEXER MODULE AND FABRICATION METHOD THEREOF

(75) Inventors: Hyun-Cheol Bae, Daejeon (KR); Jong Tae Moon, Daejeon (KR)

(73) Assignee: ELECTRONICS AND TELECOMMUNICATIONS RESEARCH INSTITUTE, Daejeon (KR)

(21) Appl. No.: 13/294,204

(22) Filed: Nov. 11, 2011

(30) Foreign Application Priority Data
Dec. 16, 2010 (KR) 10-2010-0129018

(51) Int. Cl. H03H 9/70; H01F 41/00

(52) U.S. Cl. 333/133; 29/602.1

(57) ABSTRACT

Disclosed is a fabrication method for miniaturizing a film bulk acoustic wave resonator (FBAR) duplexer module including two FBAR filters, a tuning inductor, and a phase shifter. An exemplary embodiment of the present disclosure provides a method of miniaturizing a FBAR duplexer module, including forming a tuning inductor in a multilayer printed circuit board (PCB), forming a phase shifter in the multilayer PCB, and forming at least one of a transmitting FBAR filter and a receiving FBAR filter in the multilayer PCB.

### CROSS-REFERENCE TO RELATED APPLICATIONS

This application is based on and claims priority from Korean Patent Application No. 10-2010-0129018, filed on Dec. 16, 2010, with the Korean Intellectual Property Office, the disclosure of which is incorporated herein in its entirety by reference.

### TECHNICAL FIELD

The present disclosure relates to a fabrication method for miniaturizing a film bulk acoustic wave resonator (FBAR) duplexer module and a miniaturized FBAR duplexer module apparatus.

More particularly, the present disclosure relates to a method and an apparatus for miniaturizing a FBAR duplexer module by forming a transmitting FBAR filter or a receiving FBAR filter within a multilayer printed circuit board (PCB), or by forming transmitting and receiving FBAR filters in a lower portion of a substrate.

### BACKGROUND

Currently, the miniaturization of a film bulk acoustic wave resonator (FBAR) duplexer module has proceeded from 5050 size to 3838 size and now to 3030 size. A function of the FBAR duplexer module has gradually become more complex to a triplexer, a quintplexer, and the like, using a FBAR filter.

The conventional FBAR duplexer module has been fabricated by a method of forming two FBAR filters for transmission and reception on a printed circuit board (PCB) including a tuning inductor and a phase shifter and then, configuring a module through molding.

However, there are some constraints on decreasing a size of an FBAR filter occupying the largest area in a duplexer module, and sizes of a tuning inductor and a phase shifter to configure the FBAR duplexer module of which miniaturization is continuously ongoing. Therefore, there is a need for a method of arranging FBAR filters with a new scheme.

### SUMMARY

The present disclosure has been made in an effort to provide a method of fabricating a film bulk acoustic wave resonator (FBAR) duplexer module. An existing FBAR duplexer module is fabricated by arranging FBAR filters on a printed circuit board (PCB) and then molding the same, whereas the present disclosure embodies the miniaturization of an FBAR duplexer module using a scheme of embedding FBAR filters occupying the largest area in a duplexer module.

The present disclosure has been made in an effort to provide a method capable of miniaturizing an FBAR duplexer module to comply with a light/thin/short/small characteristic, a multifunction, and a multiband characteristic that are required for a current wireless communication terminal.

An exemplary embodiment of the present disclosure provides an FBAR duplexer module including: a transmitting FBAR filter formed on an upper portion of a multilayer PCB; a receiving FBAR filter embedded in the multilayer PCB; and a tuning inductor and a phase shifter formed in the multilayer PCB.

Another exemplary embodiment of the present disclosure provides an FBAR duplexer module including: a receiving FBAR filter formed on an upper portion of a multilayer PCB; a transmitting FBAR filter embedded in the multilayer PCB; and a tuning inductor and a phase shifter formed in the multilayer PCB.

Yet another exemplary embodiment of the present disclosure provides an FBAR duplexer module including: a semiconductor chip formed on an upper portion of a multilayer PCB; a transmitting FBAR filter and a receiving FBAR filter embedded in the multilayer PCB; and a tuning inductor and a phase shifter formed in the multilayer PCB.

Still another exemplary embodiment of the present disclosure provides a fabrication method of an FBAR duplexer module, including: forming a tuning inductor within a multilayer PCB; forming a phase shifter within the multilayer PCB; and forming at least one of a transmitting FBAR filter and a receiving FBAR filter within the multilayer PCB.

According to the exemplary embodiments of the present disclosure, it is possible to decrease the overall module size by reflecting requirements of a communication part needing a gradual miniaturization, and thereby mounting FBAR filters within a PCB including an inductor and a phase shifter that are required for a module configuration.

According to the exemplary embodiments of the present disclosure, it is possible to decrease the overall module size of a module by embedding, in a PCB including an existing tuning inductor and a phase shifter, transmitting and receiving FBAR filters occupying the largest area in a duplexer module.

According to the exemplary embodiments of the present disclosure, it is possible to provide a method and an apparatus capable of miniaturizing an FBAR duplexer module to comply with a light/thin/short/small characteristic, a multifunction, and a multiband characteristic that are required for a current wireless communication terminal

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating a duplexer module in which two film bulk acoustic wave resonator (FBAR) filters for transmission and reception are formed on a printed circuit board (PCB) including a tuning inductor and a phase shifter according to a related art;

FIG. 2A is a cross-sectional view illustrating a duplexer module in which a transmitting FBAR filter is positioned on a PCB, a tuning inductor and a phase shifter are connected to each other using wire bonding, and a receiving FBAR filter is embedded in the PCB according to an exemplary embodiment of the present disclosure;

FIG. 2B is a cross-sectional view illustrating a duplexer module in which a receiving FBAR filter is positioned on a PCB, a tuning inductor and a phase shifter are connected using wire bonding, and a transmitting FBAR filter is embedded in the PCB according to an exemplary embodiment of the present disclosure;

FIG. 2C is a cross-sectional view illustrating a duplexer module in which a transmitting FBAR filter is positioned on a PCB, a tuning inductor and a phase shifter are connected using a flip chip process, and a receiving FBAR filter is embedded in the PCB according to an exemplary embodiment of the present disclosure; and

FIG. 3 is a cross-sectional view illustrating a miniaturized FBAR duplexer module in which a transmitting FBAR filter and a receiving FBAR filter are embedded in a multilayer PCB mounted with an existing semiconductor chip or a communication part for a wireless communication terminal according to another exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Hereinafter, exemplary embodiments of the present disclosure will be described in detail with reference to the accompanying drawings. The configuration and operation of the present disclosure will be clearly understood from the following description.

Prior to describing the present disclosure, like reference numerals refer to the like elements throughout. When it is determined that detailed description related to a known function or configuration may make the purpose of the present disclosure unnecessarily ambiguous, the detailed description will be omitted.

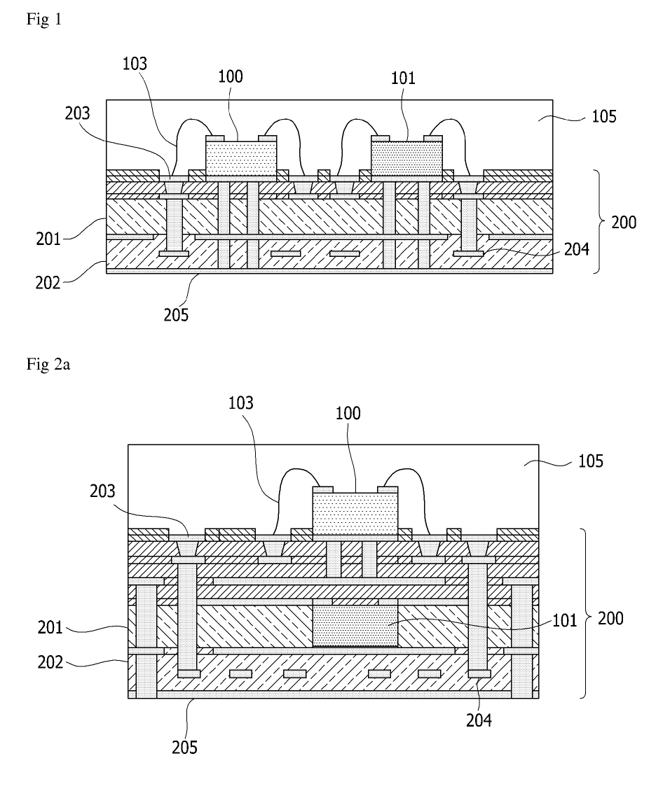

FIG. 1 illustrates a duplexer module in which a transmitting film bulk acoustic wave resonator (FBAR) filter 100 and a receiving FBAR filter 101 are formed on a multilayer printed circuit board (PCB) 200 according to a related art.

Referring to FIG. 1, two FBAR filters, that is, transmitting FBAR filter 100 and receiving FBAR filter 101 are formed on multilayer PCB 200 including a tuning inductor 203 and a phase shifter 204. Multilayer PCB 200 includes a core 201, an insulating layer 202, and a ground surface 205.

Transmitting FBAR filter 100 and receiving FBAR filter 101 may be connected to tuning inductor 203 and phase shifter 204, respectively, using wire bonding 103.

Insulating layer 202 positioned below core 201 may be formed of a low dielectric substance, and phase shifter 204 may be formed in the insulating layer 202.

A molding portion 105 may protect transmitting FBAR filter 100 and receiving FBAR filter 101, attached to multilayer PCB 200, from an external stress.

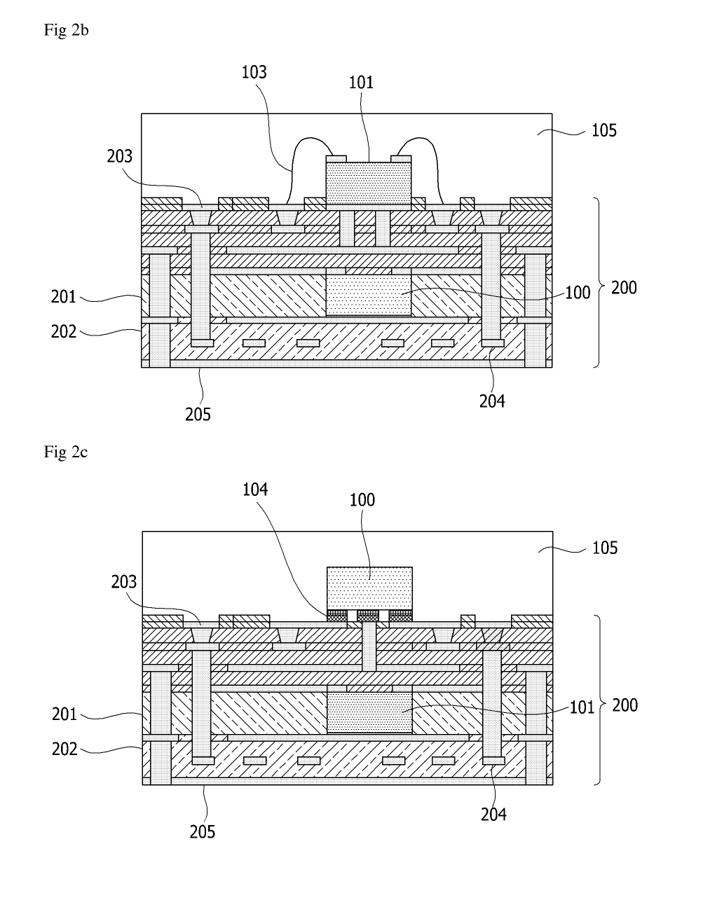

FIG. 2A illustrates an FBAR duplexer module in which receiving FBAR filter 101 is embedded in multilayer PCB 200 according to an exemplary embodiment of the present disclosure.

Referring to FIG. 2A, transmitting FBAR filter 100 is positioned on multilayer PCB 200 and receiving FBAR filter 101 is embedded in multilayer PCB 200. In a FBAR filter wafer fabricated using an FBAR, transmitting FBAR filter 100 and receiving FBAR filter 101 are fabricated through camping using silicon or a glass substrate.

Referring to FIG. 2A, tuning inductor 203 requiring a high Q-factor (Q) value is formed on the top surface of multilayer PCB 200 to maintain a distance from ground surface 205 in order to obtain the high Q value greater than or equal to a predetermined value. Tuning inductor 203 may have a single layer metal line structure or a multilayer metal line structure in which multiple layers are connected using a via.

Referring to FIG. 2A, phase shifter 204 may be formed in a lower portion of multilayer PCB 200. Phase shifter 204 may have a single layer metal line structure or a multilayer metal line structure using a via. After forming a cavity in an area corresponding to core 201 of multiplayer PCB 200, receiving FBAR filter 101 is embedded in the cavity.

After positioning pre-fabricated transmitting FBAR filter 100 on multilayer PCB 200 constructed as above through a die adhesion process, transmitting FBAR filter 100 is connected to tuning inductor 203 and phase shifter 204 through a process of wire bonding 103.

When all the connections are performed, a device may be fabricated using molding portion 105 that is formed through a molding process.

FIG. 2B illustrates an FBAR duplexer module having the same fabrication process as shown in FIG. 2A, however, embedding transmitting FBAR filter 100 in multilayer PCB 200. Referring to FIG. 2B, receiving FBAR filter 101 is positioned on multilayer PCB 200 and transmitting FBAR filter 100 is embedded in multilayer PCB 200.

FIG. 2C illustrates an FBAR duplexer module in which receiving FBAR filter 101 is embedded in multilayer PCB 200, tuning inductor 203 and phase shifter 204 are connected using a flip chip process, and transmitting FBAR filter 100 is positioned on multilayer PCB 200 according to an exemplary embodiment of the present disclosure.

After positioning pre-fabricated transmitting FBAR filter 100 on multilayer PCB 200 through a die adhesion process, transmitting FBAR filter 100 is connected to tuning inductor 203 and phase shifter 204 through the flip chip process using a bump 104 or a solder.

When all the connections are performed, a device may be fabricated using molding portion 105 that is formed through a molding process.

Even though FIG. 2C illustrates a structure in which transmitting FBAR filter 100 is formed on multilayer PCB 200 and receiving FBAR filter 101 is embedded in multilayer PCB 200, receiving FBAR filter 101 may be formed on multilayer PCB 200 and transmitting FBAR filter 100 may be embedded in multilayer PCB 200 through the above same fabrication process.

In the FBAR duplexer module shown in FIG. 2A, 2B, and 2C, transmitting FBAR filter 100 or receiving FBAR filter 101 is embedded in multilayer PCB 200 and thus, it is possible to decrease the overall module size.

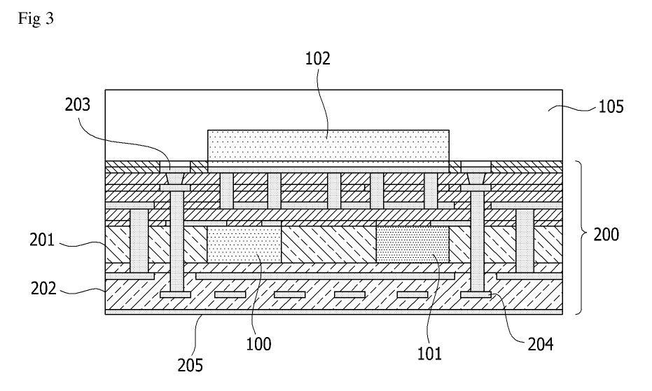

FIG. 3 illustrates an FBAR duplexer module in which transmitting FBAR filter 100 and receiving FBAR filter 101 are embedded in multilayer PCB 200 according to another exemplary embodiment of the present disclosure.

Unlike the FBAR duplexer module of FIG. 2A, 2B, and 2C, the FBAR duplexer module of FIG. 3 has a configuration in which a device having the largest area such as a semiconductor chip 102 constituting a wireless terminal is disposed in an upper portion of multilayer PCB 200 and both transmitting and receiving FBAR filters 100 and 101 are embedded in multilayer PCB 200.

Tuning inductor 203 and phase shifter 204 may have a single layer metal line structure or a multilayer metal line structure using a via. Also, after forming two cavities in an area corresponding to core 201 of multilayer PCB 200, transmitting and receiving FBAR filters 100 and 101 may be embedded in the cavities, respectively.

Molding portion 105 protects semiconductor chip 102, attached to multilayer PCB 200, from an external stress.

As described above, in FBAR duplexer module of FIG. 3, all of transmitting and receiving FBAR filters 100 and 101 are mounted within multilayer PCB 200 including tuning inductor 203 and phase shifter 204 and thus, it is possible to decrease the overall module size.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A film bulk acoustic wave resonator (FBAR) duplexer module comprising:
a transmitting FBAR filter formed on an upper portion of a multilayer printed circuit board (PCB);
a receiving FBAR filter embedded in the multilayer PCB; and
a tuning inductor and a phase shifter formed in the multilayer PCB.

2. The FBAR duplexer module of claim 1, wherein the tuning inductor and the phase shifter have a single layer metal line structure or a multilayer metal line structure in which multiple layers are connected using a via.

3. An FBAR duplexer module comprising:
a receiving FBAR filter formed on an upper portion of a multilayer PCB;
a transmitting FBAR filter embedded in the multilayer PCB; and
a tuning inductor and a phase shifter formed in the multilayer PCB.

4. The FBAR duplexer module of claim 3, wherein the tuning inductor and the phase shifter have a single layer metal line structure or a multilayer metal line structure in which multiple layers are connected using a via.

5. An FBAR duplexer module comprising:
a semiconductor chip formed on an upper portion of a multilayer PCB;
a transmitting FBAR filter and a receiving FBAR filter embedded in the multilayer PCB; and
a tuning inductor and a phase shifter formed in the multilayer PCB.

6. The FBAR duplexer module of claim 5, wherein the tuning inductor and the phase shifter have a single layer metal line structure or a multilayer metal line structure in which multiple layers are connected using a via.

7. A fabrication method of an FBAR duplexer module, comprising:
forming a tuning inductor in a multilayer PCB;
forming a phase shifter in the multilayer PCB; and
forming at least one of a transmitting FBAR filter and a receiving FBAR filter in the multilayer PCB.

8. The method of claim 7, wherein the tuning inductor and the phase shifter have a single layer metal line structure or a multilayer metal line structure in which multiple layers are connected using a via.

9. The method of claim 7, wherein the tuning inductor is formed on an upper surface of the multilayer PCB to maintain a distance from a ground surface in order to obtain Q value greater than or equal to a predetermined value.

10. The method of claim 7, wherein:
when the transmitting FBAR filter is formed in the multilayer PCB, the receiving FBAR filter is formed on an upper portion of the multilayer PCB, and
when the receiving FBAR filter is formed in the multilayer PBC, the transmitting FBAR filter is formed on the upper portion of the multilayer PCB.

11. The method of claim 10, wherein the transmitting FBAR filter or the receiving FBAR filter positioned on the multilayer PCB is connected to the tuning inductor and the phase shifter by a wire bonding process or a flip chip bonding process.

12. The method of claim 7, wherein the forming of at least one of the transmitting FBAR filter and the receiving FBAR filter in the multilayer PCB comprises:
forming at least one cavity in the multilayer PCB; and
embedding at least one of the transmitting FBAR filter and the receiving FBAR filter in the at least one cavity.
